(19) United States
(12) Patent Application Publication
(10) Pub. No.: US 2012/0204951 A1
(43) Pub. Date: Aug. 16, 2012

(54) PHOSPHOR-CONTAINED SOLAR CELL AND METHOD THEREOF

(76) Inventors: Chung-Yu WANG, New Taipei City (TW); Yi-Fang CHEN, Taichung City (TW)

(21) Appl. No.: 13/302,378

(22) Filed: Nov. 22, 2011

(30) Foreign Application Priority Data
Feb. 15, 2011 (TW) 100104935

(51) Int. Cl. H01L 31/0232; H01L 31/18

(52) U.S. Cl. 136/257; 438/57; 257/E31.001

(57) ABSTRACT

A phosphor-contained solar cell comprises a photoelectric conversion layer for conversing the photo energy to electrical energy; a phosphor layer, disposed on at least one side of the photoelectric conversion layer, for improving the photoelectric conversion efficiency; the phosphor is up conversion phosphor or down conversion phosphor; wherein the up conversion phosphor is selected from X₂Mo₂O₉:X or X₂Mo₂O₉:X,X; the down-conversion phosphor is selected from JQX(PO₄)₂:X³⁺ or JQX(PO₄)₂:X²⁺,X²⁺; wherein X represents anyone of rare earth metal, J represents lithium, sodium or potassium, Q represents anyone of alkaline earth metal.

### CROSS-REFERENCE TO RELATED APPLICATION

This non-provisional application claims priority under 35 U.S.C. §119(a) on Patent Application No(s). 100104935 filed in Taiwan, R.O.C. on Feb. 15, 2011, the entire contents of which are hereby incorporated by reference.

### FIELD OF THE INVENTION

This invention related to a solar cell, more particularly, to a phosphor-contained solar cell and the method thereof.

### BACKGROUND OF THE INVENTION

Developing the self-production green energy is the most important subject of the human being because of the double demand of the energy crunch and the environmental issue. The solar energy is one of the best of the renewable energy because of universality, self-production and environmental protection. The solar cell transfers the solar energy into electrical energy directly. No toxic material, greenhouse gas and noise will be produced during its operation. Thus, its operation is quiet safe. Only inexpensive maintenance cost is needed. Moreover, the solar energy is inexhaustible and renewable ideal energy; thus developing the related material and technology of the solar cell is the best way and strategy to solve the current problem of energy and environmental issue.

Currently, the development of the solar cell can be divided into two types. The first type is the silicon base material. The second type is the non-silicon base material. At the present time, the more development second type is compound semiconductor (such as CdTe), dye sensitized solar cell (DSSC) or organic battery, etc. At the present stage, the major development of the solar cell is the first type because the higher conversion efficiency of the solar cell made by the silicon base material. The silicon base material can be divided into: monocrystalline silicon, polycrystalline silicon, amorphous silicon and silicon film, etc. Currently, in the solar cell market, the major solar cell is monocrystalline silicon, polycrystalline silicon. The conversion efficiency of the commercial monocrystalline silicon is about 20%. As for the polycrystalline silicon, the conversion efficiency is about 17%. These are far away from the ideal target of the conversion efficiency since the ideal conversion efficiency in the lab reach 30%-40%, respectively. Thus, how to improve the conversion efficiency is very important development target.

In 2002, Trupke et al. disclosed the improved efficiency of the third generation solar cell (non-patent reference 1), wherein using the up and down conversion phosphor for improving the conversion efficiency is mentioned, as shown in FIG. 1. That's because the silicon base material solar cell only absorbed bandwidth from 400 nm to 1000 nm of the sunlight to proceed the photoelectric conversion because of the limitation of the energy level of the silicon element. However, in the general sunlight spectrum, the coverage of the sunlight is from UV light to IR light. Thus, the absorption range of the silicon material is obviously narrow. Therefore, the conversion efficiency can be improved significantly if the usage of the UV light region and the IR light region can be increased.

Generally, the conversion of the frequency spectrum or the optical spectrum can be used with appropriate phosphor material and performed by the following three ways: the up conversion (structure shown in FIG. 1(a)), the down conversion (structure shown in FIG. 1(b)) and the spectral concentration. The theory of the up conversion of the sunlight spectrum is transferring the incident photon, which has energy smaller than the energy gap of the solar cell material, into the photon, which has energy higher than the energy gap. Then, the high energy photon, generated by the reflection of the reflection mirror, is absorbed by the solar cell again and forms the electron-hole pair. The highest theoretical efficiency is 47.6%. The theory of the down conversion of the sunlight spectrum is forming the down converter on the surface of the solar cell and then transferring the incident photon, which has energy greater more than twice of the energy gap of the solar cell material, into two photos, which has energy greater than the energy gap. After that, it will be absorbed by the solar cell again and generated two electron-hole pairs. The highest theoretical efficiency is 30.9%. The third option is the spectral concentration, which is to integrate the advantages of both up/down conversions. The spectrum of the incident sunlight converse concentrated into near the energy gap slightly greater than the solar cell material. Thus, the incident photon, which has energy smaller then the energy gap, is up conversed into high energy photon. The incident photon, which has energy higher twice of the energy gap, is down conversed into low energy photon. Finally, the conversion efficiency can be improved effectively. The highest theoretical efficiency depends on the variety of the up/down conversion material and the coupling of two structures.

Currently, the up conversion phosphor of the solar cell disclosed in the prior art is NaYF₄:Er (non-patent reference 2) and NaYF₄:Yb,Er (non-patent reference 3), which can improve the quantum efficiency of the solar cell. The down conversion phosphor of the solar cell disclosed in the prior art is Y₂O₃:Eu³⁺ or Y₂O₂S:Eu³⁺ (non-patent reference 4), for example. It can be used by combining with the polymer (PE and TPP) and then coating on the lab type small size solar cell.

US Patent Application No. 2007/0295383 A1 disclosed a serious of nanometer and micrometer phosphor, which absorb wavelength of (Sr,Ba,Eu)₂SiO₄Fₓ from 280 nm to 460 nm, integrated with the silicon solar cell to improve the conversion efficiency thereof. However, the prior technology does not clearly provide the data which can improve the conversion efficiency effectively but only apply to the solar cell with lab type small size. Thus, it lacks of the commercial application for mass production.

Theoretically, it had been confirmed that one of the practicable ways to improve the conversion efficiency of the solar cell is utilizing the photo conversion material (variety of the phosphor material). The major advantages is simple, low cost, not influence the current method for making the solar cell and also theoretically suitable for variety of the solar cell. Thus, it is believed that seeking and practicing the photo conversion material, which can be applied to the solar cell, influences the spread and the development of the solar cell significantly. Therefore, the worldwide research institutions are dedicated to develop the alternative material and the related technology to decrease the cost and improve the conversion efficiency.

Therefore, this invention desired to disclose a phosphor-contained solar cell to improve the photoelectric conversion efficiency of the solar cell effectively.
Non-patent reference 1: T. Trupkea et al. (2002), J. Appl. Phys., 92, 3, 1668-1674.
Non-patent reference 2: A. Shalav et al. (2005), Appl. Phys. Lett. 86, 013505.
Non-patent reference 3: A. Shalav et al. (2007), Sol. Energ. Mat. Sol. Cells, 91, 829-842.
Non-patent reference 4: P. Chung et al. (2007), J. Vac. Sci. Technol. A, 25, 1, 61-66.

### SUMMARY OF THE INVENTION

In view of the disadvantages of the prior technology, the applicant realized that it is not perfect and try his best to overcome the disadvantages above-mentioned. Relying on the experiment in this technology field, the applicant developed a phosphor-contained solar cell to achieve the purpose of improving the photoelectric conversion efficiency of the solar cell.

The major object of this invention is to provide a phosphor-contained solar cell, which can improve the photoelectric conversion efficiency of the solar cell effectively.

To achieve the object above-mentioned, this invention disclosed a phosphor-contained solar cell comprising a photoelectric conversion layer for conversing the photo energy to electrical energy; a phosphor layer, disposed on at least one side of the photoelectric conversion layer, for improving the photoelectric conversion efficiency; the phosphor is up conversion phosphor or down conversion phosphor; wherein the up conversion phosphor is selected from X₂Mo₂O₉:X or X₂Mo₂O₉:X,X; the down conversion phosphor is selected from JQX(PO₄)₂:X³⁺ or JQX(PO₄)₂:X²⁺,X²⁺; wherein X represents anyone of rare earth metal, J represents lithium, sodium or potassium, Q represents anyone of alkaline earth metal.

In the solar cell above-mentioned, the up conversion phosphor is La₂Mo₂O₉:Yb, Er or La₂Mo₂O₉:Yb,Ho.

In the solar cell above-mentioned, the down conversion phosphor is KCaGd(PO₄)₂:Eu³⁺ or KSrGd(PO₄)₂:Eu³⁺.

In the solar cell above-mentioned, the phosphor layer further comprises BaMgAl₁₀O₁₇:Eu²⁺,Mn²⁺ or (Ba,Sr,Mg)₂SiO₄:Eu²⁺.

In the solar cell above-mentioned, the phosphor layer further comprises a polymer coating; selected from one of polymethyl methacrylate (PMMA), polyamide, silicone and the combination thereof.

In the solar cell above-mentioned, the photoelectric conversion layer is selected from one of P-type semiconductor and N-type semiconductor or the combination thereof.

In the solar cell above-mentioned, the photoelectric conversion layer is selected from one of polycrystalline silicon, monocrystalline silicon, amorphous silicon, CdTe or the combination thereof.

The solar cell above-mentioned further comprises an anti-reflection layer, which is disposed on at least one side of the photoelectric conversion layer, between the photoelectric conversion layer and the phosphor layer or on at least one side of the phosphor layer.

In the solar cell above-mentioned, the anti-reflection layer is selected from one of silicon nitride, silicon oxide, silicon oxynitride or the combination thereof.

In the solar cell above-mentioned, the phosphor layer is formed by screen printing, evaporation, sputtering, coating, coating with aluminum paste or adhesion.

In the solar cell above-mentioned, forming the phosphor powder on the mother line of the solar cell needs to be avoided. The mother line is also called the bus bar or the bus line. FIGS. 2(a) and 2(b) show solar cells having the bus bar with two lines or three lines respectively.

In the solar cell above-mentioned, the thickness of the phosphor layer is from 1 to 100 micrometers.

Therefore, this invention disclosed a phosphor-contained solar cell, which can improve the photoelectric conversion efficiency of the solar cell effectively.

### BRIEF DESCRIPTION OF THE DRAWINGS

FIGS. 1(a) to 1(b) depict the solar cell structure with the up conversion phosphor and the down conversion phosphor respectively; and

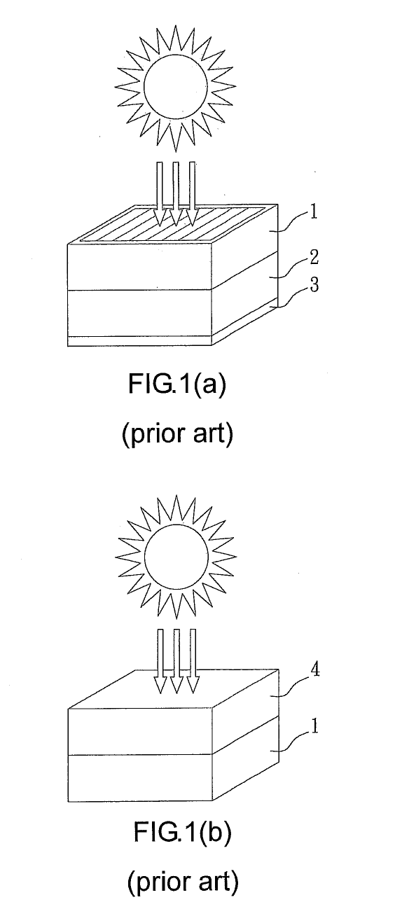

FIGS. 2(a) and 2(b) illustrated solar cells having the bus bar with two lines or three lines respectively.

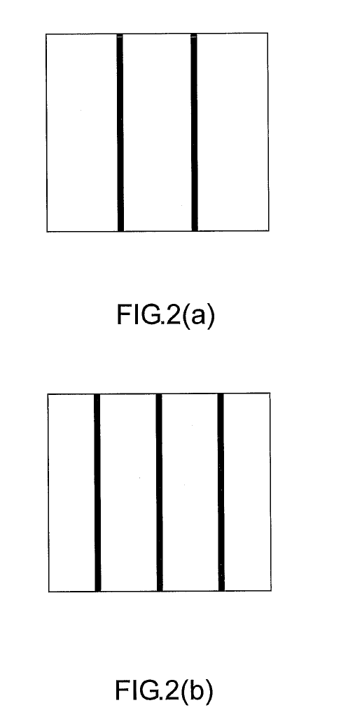

### DETAILED DESCRIPTION OF THE PREFERRED EMBODIMENTS

In summary, the major object of this invention is to provide a solar cell having a photoelectric conversion layer and a phosphor layer, wherein the phosphor layer comprising the up conversion phosphor or the down conversion phosphor.

Generally speaking, the general formula of the up conversion phosphor is X₂Mo₂O₉:X or X₂Mo₂O₉:X,X, wherein the X represents anyone of rare earth metal, such as La, Gd, etc. Moreover, the up conversion phosphor is doped with one or two kind of rear earth metal.

The general formula of the down conversion phosphor is JQX(PO₄)₂:X³⁺ or JQX(PO₄)₂:X²⁺,X²⁺, wherein J represents lithium, sodium or potassium, Q represents anyone of alkaline earth metal such as Mg, Ca, Sr, Ba. The definition of X is the same as previous. Beside, the down conversion phosphor is doped with one or two kind of rear earth metal.

To fully understand the purpose, feature and function of this invention, this invention is described as below by utilizing the preferred embodiments and the drawings:

Synthesizing the Up Conversion Phosphor La₂Mo₂O₉:Yb,Er and La₂Mo₂O₉:Yb,Ho

La₂O₃, MoO₃, Yb₂O₃ and R₂O₃ (R═Er, Ho) were mixed by the stoichiometric ratio (1-x-y):2:x:y, wherein x=0.09 and y=0.01. The mixture was dissolved in the 5% HCl. After drying, a pale yellow powder precursor was obtained. Then, the precursor was fully mixed and grinded. And then, after heating at 900° C. for 8 hours and cooling slowly, high purity white La₂Mo₂O₉:Yb,Er and La₂Mo₂O₉:Yb,Ho were obtained.

Synthesizing the Down Conversion Phosphor KCaGd(PO₄)₂:Eu³⁺ and KSrGd(PO₄)₂:Eu³⁺

(NH₄)₂HPO₄, K₂CO₃, Eu₂O₃, Gd₂O₃ and RCO₃ (R═Ca, Sr) were mixed by the stoichiometric ratio and then mixed with the NH₄Cl functioning as flux. Cooling slowly after heating at 800° C. for 6 hours and then heating at 1200° C. for 6 hours, high purity KCaGd(PO₄)₂:Eu³⁺ and KSrGd(PO₄)₂:Eu³⁺ were obtained.

Manufacturing the Solar Cell Having the Up Conversion Phosphor

The up conversion phosphor and PMMA were mixed by the weight percent of 1:10 and then coated on a 6″×6″ polycrystalline silicon solar panel by screen printing. Finally, the solar cell having the up conversion phosphor was performed after curing at 130° C. for 3 hours. In the embodiment 1, the La₂Mo₂O₉:Yb,Ho was coated on the light incident surface of the solar cell. In the embodiments 2 and 3, the La₂Mo₂O₉:Yb,Er was coated on the light incident surface of the solar cell. In the embodiment 4, La₂Mo₂O₉:Yb,Er was coated on the back light surface of the solar cell. The short current (Isc) before coating and after coating, the open circuit voltage (Voc) and the photoelectric conversion efficiency (η%) were measured respectively. The photoelectric conversion efficiency can be obtained by calculating the following equation: η=FF.Isc.Voc/Pin, wherein the Pin represents the irradiation energy, FF represents the fill factor. The experiment results are shown in Table 1:

TABLE 1

| | Isc | Isc | | η | η | |
|---|---|---|---|---|---|---|
| | (before | (after | | (before | (after | |
| embodiment | coating) | coating) | □Isc | coating) | coating) | □η |
| 1 | 8.05 | 8.18 | 0.13 | 16.53 | 16.78 | 0.25 |
| | | | | | | (+1.50%) |
| 2 | 8.04 | 8.19 | 0.13 | 16.52 | 16.81 | 0.29 |
| | | | | | | (+1.76%) |
| 3 | 8.06 | 8.21 | 0.15 | 16.53 | 16.80 | 0.27 |
| | | | | | | (+1.73%) |
| 4 | 8.13 | 8.31 | 0.18 | 16.23 | 16.67 | 0.44 |
| | | | | | | (+2.71%) |

As shown in Table 1, in the solar cell having the up conversion phosphor, the photoelectric conversion efficiency is significantly increased up to 1.50% to 2.71%. The optimum photoelectric conversion efficiency is obtained when the up conversion phosphor was coated on the back light surface of the solar panel. However, the photoelectric conversion efficiency doesn't change too much when the up conversion phosphor was coated on the light incident surface. These results conform to the theory that prior art disclosed.

Manufacturing the Solar Cell Having the Down Conversion Phosphor

The down conversion phosphor and PMMA were mixed by the weight percent of 1:10 and then coated on the light incident surface of 36 pieces of 6″×6″ commercial polycrystalline silicon solar panel by screen printing. Finally, the solar cell having the down conversion phosphor was performed after curing at 130° C. for 3 hours. The short current (Isc) before coating and after coating, the open circuit voltage (Voc) and the photoelectric conversion efficiency (q %) were measured respectively and then averaged. The experiment results are shown in Table 2:

TABLE 2

| | Isc | Isc | | η | η | |
|---|---|---|---|---|---|---|
| | (before | (after | | (before | (after | |
| embodiment | coating) | coating) | □Isc | coating) | coating) | □η |
| Average | 8.10 | 8.35 | 0.25 | 16.52 | 17.00 | 0.48 |
| value | | | | | | (+2.90%) |

As shown in Table 2, in the solar cell having the down conversion phosphor, the photoelectric conversion efficiency is significantly increased up to 2.90% and available for commercial production.

As shown on the experiment result above-mentioned, the photoelectric conversion efficiency of the solar cell can be increased effectively by coating the up and down conversion phosphor, disclosed in this invention, on the anti-reflection layer of the commercial solar panel with the anti-reflection layer or the solar panel without the anti-reflection layer and having the effect just like the anti-reflection layer.

As above-mentioned, this invention meets three requirements of patentability: novelty, non-obviousness and industrial applicability. As for the novelty and non-obviousness, this invention improves the effect of the short circuit and the photoelectric conversion efficiency of the solar cell by synthesizing the up and down conversion phosphor. As for the industrial applicability, the derivation products of this invention satisfy the requirement of the market.

While the present invention has been particularly shown and described with respect to preferred embodiments thereof, it will be understood by those skilled in the art that the embodiment only used to describe the present invention and not to limit the scope of the invention. It should be noted that any changes or replacement will fall within the scope of the present invention. Thus, the scope of present invention should be determined by appended Claims.

What is claimed is:

1. A phosphor-contained solar cell, comprising:
a photoelectric conversion layer for conversing the photo energy to electrical energy;
a phosphor layer, disposed on at least one side of the photoelectric conversion layer, for improving the photoelectric conversion efficiency;
the phosphor is up conversion phosphor or down conversion phosphor; wherein the up conversion phosphor is selected from X₂Mo₂O₉:X or X₂Mo₂O₉:X,X; the down conversion phosphor is selected from JQX(PO₄)₂:X³⁺ or JQX(PO₄)₂:X²⁺,X²⁺; wherein X represents anyone of rare earth metal, J represents lithium, sodium or potassium, Q represents anyone of alkaline earth metal.

2. The phosphor-contained solar cell according to claim 1, wherein the up conversion phosphor is La₂Mo₂O₉:Yb,Er or La₂Mo₂O₉:Yb,Ho.

3. The phosphor-contained solar cell according to claim 1, wherein the down conversion phosphor is KCaGd(PO₄)₂:Eu³⁺ or KSrGd(PO₄)₂:Eu³⁺.

4. The phosphor-contained solar cell according to claim 1, wherein the phosphor layer further comprising BaMgAl₁₀O₁₇:Eu²⁺,Mn²⁺ or (Ba, Sr, Mg)₂SiO₄:Eu²⁺.

5. The phosphor-contained solar cell according to claim 1, wherein the phosphor layer further comprising a polymer coating, selected from one of PMMA, polyamide, silicone and the combination thereof.

6. The phosphor-contained solar cell according to claim 1, wherein the photoelectric conversion layer is selected from the P-type semiconductor and N-type semiconductor or the combination thereof.

7. The phosphor-contained solar cell according to claim 1, wherein the photoelectric conversion layer is selected from one of polycrystalline silicon, monocrystalline silicon, amorphous silicon, CdTe or the combination thereof.

8. The phosphor-contained solar cell according to claim 1, further comprises an anti-reflection layer, disposed on at least one side of the photoelectric conversion layer, between the photoelectric conversion layer and the phosphor layer or on at least one side of the phosphor layer.

9. The phosphor-contained solar cell according to claim 8, wherein the anti-reflection layer is selected from one of silicon nitride, silicon oxide, silicon oxynitride or the combination thereof.

10. The phosphor-contained solar cell according to claim 1, wherein the phosphor layer is formed by screen printing, evaporation, sputtering, coating, coating with aluminum paste or adhesion.

11. The phosphor-contained solar cell according to claim 10, wherein forming the phosphor powder on the mother line of the solar cell needs to be avoided.

12. The phosphor-contained solar cell according to claim 1, wherein the thickness of the phosphor layer is from 1 to 100 micrometers.

13. A method for making the phosphor-contained solar cell, manufacturing the solar cell according to claim 1.
